(19) United States
(12) Patent Application Publication
(10) Pub. No.: US 2009/0102490 A1
(43) Pub. Date: Apr. 23, 2009

(54) APPARATUS FOR PERFORMING A STRESS TEST TO ISOLATE AND MEASURE NOISE IN A PAIRED LINE AND METHOD FOR PERFORMING A STRESS TEST TO ISOLATE AND MEASURE NOISE IN A PAIRED LINE

(76) Inventors: Curtis Clifford Taylor, Dallas, TX (US); Edwin Glenn Yancey, Burleson, TX (US)

Correspondence Address: TREXLER, BUSHNELL, GIANGIORGI,;BLACKSTONE & MARR, LTD., 105 WEST ADAMS STREET, SUITE 3600, CHICAGO, IL, 60603, US

(21) Appl. No.: 12/253,595

(22) Filed: Oct. 17, 2008

Related U.S. Application Data
(60) Provisional application No. 60/980,523, filed on Oct. 17, 2007.

(51) Int. Cl. G01R 29/26

(52) U.S. Cl. 324/613

(57) ABSTRACT

The present invention provides a circuit for performing a stress test on a paired line. The circuit provides for first and second balanced outlet pathways for applying an AC signals to the paired line. Although each of these first and second balanced outlet pathways include balanced capacitors, the need to vet these capacitors in order to achieve proper operation of the circuit is eliminated.

This application claims the domestic benefit of U.S. Provisional Application Ser. No. 60/980,523, filed on Oct. 17, 2007, which disclosure is incorporated herein by reference in its entirety.

### FIELD OF THE INVENTION

This invention is generally directed to detection of noise in a paired line. More particularly the present invention relates to an apparatus and method of measuring noise in a paired telecommunications line. The present invention is particularly, though not exclusively, an apparatus and method for detecting and isolating noise-creating imbalances in a paired line of a telecommunications cable by means of a balanced circuit.

### BACKGROUND OF THE INVENTION

Paired lines are a conventional means of carrying telecommunications transmissions. A paired line is made up of two balanced conductors individually insulated and twisted together. Paired lines are typically bundled together in a cable termed a paired cable, which contains up to one hundred or more paired lines, wherein each paired lines is capable of independently carrying telecommunications signals. Paired lines are typically effective telecommunications carriers, however, it is not uncommon for noise to occur in paired lines which is extremely disruptive to the clarity of the transmitted signal.

Test instruments have been developed that contain circuitry suitable to detect and isolate noise-creating imbalances so that a technician can diagnose the source of the problem and eliminate it. This is commonly referred to as the stress test. U.S. Pat. No. 5,157,336 (“the '336 patent”) and U.S. Pat. No. 5,302,905 (“the '905 patent) disclose circuitry of a test instrument that satisfies this need and their content is incorporated herein by reference in their entirety.

A prior art circuit 10 for performing a stress test, such as that described in the '905 patent is shown in FIG. 1. The circuit 10 includes a first balanced outlet pathway 12 in electrical communication with a first conductor of a telecommunications pair through a first contact 14, and a second balanced outlet pathway 16 in electrical communication with the second conductor of a telecommunications pair through a second contact 18. An alternating current source 20 provides an alternating current signal that is communicated to the first and second conductors through the first and second balanced pathways 12, 16 respectively to determine whether the conductors are in fact electrically balanced. The circuit 10 also includes a first high voltage bias pathway 22 in electrical communication with the first conductor of a telecommunications pair and a second high voltage bias pathway 24 in electrical communication with a second conductor of the telecommunications pair. A direct current source 26 is connected to the first and second conductors through the first and second high voltage bias pathways 22, 24 respectively so that faults that have been concealed by galvanic action can be punched through by the DC current and detected by the AC signal provided by the alternating current source 20. Measuring circuitry is provided by a differential amplifier 21 which detects and measures any imbalance between voltage inlet passageways 28, 30.

As shown in FIG. 1 the first balanced outlet pathway 12 includes resistor 32 and capacitor 34 and second balanced outlet pathway 16 includes resistor 36 and capacitor 38. Capacitors 34, 38 prevent unwanted DC current from damaging the measuring circuitry 21. In addition capacitors 34, 38 supply the AC current signal to the conductors. The AC signal passes through the capacitors 34, 38 a first time when the signal is provided to the telecommunications pair and a second time when the signal is reflected back from the telecommunications pair and is provided to the differential amplifier 21. Because the AC signal, generated by the alternating current source 20 and used to perform the stress test, passes through capacitors 34, 38 two times, any difference between the values of the capacitors 34, 38 is multiplied and a false indication of imbalance for the telecommunications pair can result easily. Thus, it is important that the capacitors 34, 38 are properly matched.

In order to ensure balance of the first and second pathways 12, 16, a technician must examine a number of capacitors that have been pre-sorted by the manufacturer to locate two capacitors having values within 0.5% of one another. After the capacitors have been installed, the capacitors are further matched to be within 0.05% of each other. These steps to match the capacitors are necessary to ensure that the circuit 10 will operate properly. Because capacitors are inherently difficult to manufacture in tight tolerances, the technician can not simply rely on the pre-sorted values provided by the manufacturer. Furthermore, because capacitor values drift with temperature and age, the value of the capacitor may vary from the value at the time of manufacture.

It is inefficient, costly, and unreliable to have a technician perform this vetting operation. Consequently, there is a need for circuitry that can perform the necessary functions of a stress test as described in the '336 and '905 patents in a more efficient, economical and reliable manner.

The present invention provides a circuit and method which overcomes the problems presented in the prior art and which provides additional advantages over the prior art, such advantages will become clear upon a reading of the attached specification in combination with a study of the drawings.

### SUMMARY OF THE INVENTION

The present invention provides a circuit and a method of measuring noise in a paired line which does not require vetting of capacitors to ensure balance between a first balanced inlet pathway and a second balanced inlet pathway.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein like reference numerals identify like elements in which:

FIG. 1 is a diagram of a prior art circuit for measuring noise in a paired line;

FIG. 2 is a perspective view of the present invention shown connected to a schematically depicted telephone system having a paired line; and

FIG. 3 is a diagram of the circuit of the present invention for measuring noise in a paired line.

### DETAILED DESCRIPTION OF THE ILLUSTRATED EMBODIMENTS

While the invention may be susceptible to embodiment in different forms, there is shown in the drawings, and herein will be described in detail, a specific embodiment with the understanding that the present disclosure is to be considered an exemplification of the principles of the invention, and is not intended to limit the invention to that as illustrated and described herein.

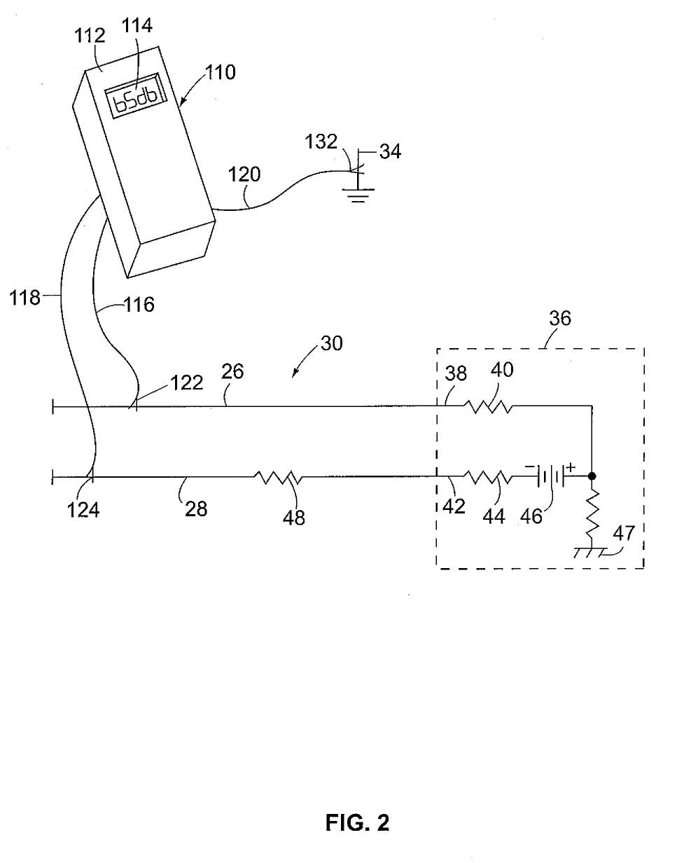

Referring first to FIG. 2, the noise measuring device of the present invention is shown and generally designated 110. As will be described herein below, the noise measuring device 110 is used to detect noise in a paired line 30. The paired line 30 includes first and second conductors 26, 28 which terminate at a central telephone office 36. Central telephone offices are generally characterized as having balanced input circuits, i.e. balanced impedance to ground. Central office 36 shown in FIG. 2 is representative of such offices, wherein balanced circuits are provided by a first terminal 38 having a resistor 40 and a second terminal 42 having an equal resistor 44. Terminal 42 further has a direct current battery 46 in series. Both terminals 38 and 42 lead to ground 47. Battery 46 supplies the operating current to the telephone loop which is defined by paired line 30.

A series resistance fault 48 is shown on second conductor 28 which creates an imbalance in paired line 30 between first and second conductor 26, 28. It is understood that fault 48 is illustrative of any number of sources of imbalance in paired line 30 to which the present invention is applicable, including shunt resistance faults, cross faults, shunt capacitance faults, unbalanced series inductance, and power influence.

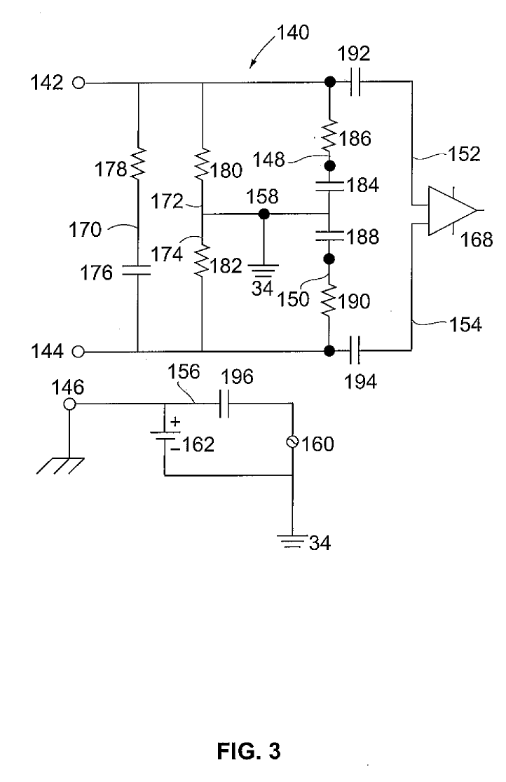

The internal circuit of the device 110 is shown in FIG. 3 and is contained within the housing 112. A display 114, such as a liquid crystal display, is provided through housing 112 for visually displaying measured noise or balance values to an operator. First measuring lead 116, second measuring lead 118, and ground lead 120 extend from housing 112. First measuring lead 116 includes a first contact 122 affixed on an end thereof, second measuring lead 118 includes a second contact 124 affixed on an end thereof and ground lead 120 has a ground contact 132 affixed on an end thereof. First contact 122 is removably engagable with the first conductor 26, second contact 124 is removably engagable with the second conductor 28 and ground contact 132 is removably engagable with an earth ground 134. Contacts 122, 124, 132 are preferably conventional alligator clips which are toothed and spring biased to made good electrical contact upon engagement with conductors 26, 28 or ground 34 and yet are easily removable for repositioning.

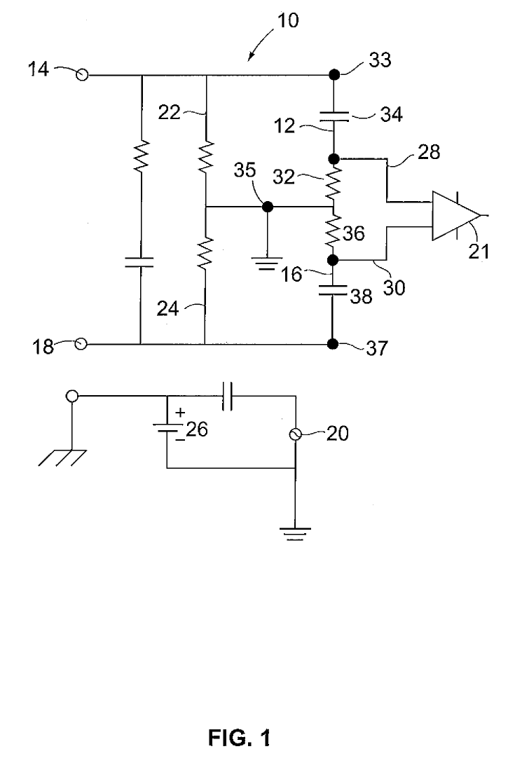

Referring now to FIG. 3, a preferred embodiment of the internal circuit of device 110 is shown and generally designated 140. The internal circuit 140 is substantially the same as the prior art circuit 10 shown in FIG. 1.

The circuit 140 includes a first contact 142, a second contact 144, and a third contact 146. The first contact 42 provides external connection to the first conductor 26 of the paired line 30 through contact 122 and lead 116, the second contact 144 provides external connection to the second conductor 28 of the paired lines 30 through contact 124 and lead 118, and the third contact 146 provides external connection to the earth ground 34 through contact 32 and lead 120.

As also shown in FIG. 3 the internal circuit 140 generally includes a ground pathway 156, a first balanced outlet pathway 148, a second balanced outlet pathway 150, a first high voltage bias pathway 180, a second high voltage bias pathway 182, a terminating pathway 170, a first voltage inlet pathway 152, and a second voltage inlet pathway 154. A node 158 provides connection of the internal circuit 140 to earth ground.

The ground pathway 156 generally includes an oscillator 160, a dc power source 162 and an ac blocking capacitor 196. The ac blocking capacitor 196 prevents the ground pathway 156 from drawing ac power influence current to ground to undesirably seal fault 48. In addition, capacitor 196 minimizes low frequency ac power influence current and the de loop current drawn by the ground pathway 156. The oscillator 160 provides a low voltage alternating current source feeding into conductors 26, 28 across the first and second balanced outlet pathways 148, 150. Low voltage ac is defined herein as preferably being less than about 10 volts.

First balanced outlet pathway 148 extends from earth ground 158 to the first conductor 26 through the first contact 142. The first balanced outlet pathway 148 includes a first balanced capacitor 184 and a first balanced resistor 186. Capacitor 184 preferably has a value of 2.2 μF and resistor 186 preferably has a value of 1 KΩ. Second balanced outlet pathway 150 extends from earth ground 158 to second conductor 28 through the second contact 144. The second balanced outlet pathway includes a second balanced capacitor 188 and a second balanced resistor 190. Capacitors 184, 188 are matched within 0.5%. Capacitor 188 preferably has the same value as capacitor 184 and thus preferably has a value of 2.2 μF. Resistor 190 preferably has the same value as resistor 186 and thus preferably has a value of 1 KΩ.

The first high voltage bias pathway 172 extends from earth ground 158 to the first conductor 26 through the first contact 142. The first high voltage bias pathway includes a high value resistor 180 which preferably has a value of 100 KΩ. Second high voltage bias pathway 174 extends from earth ground 158 to the second conductor 28 through second contact 144. The second high voltage bias pathway includes a high value resistor 182 which preferably has the same value as resistor 180.

Terminating pathway 170 is provided between first contact 142 second contact 144. Terminating pathway 170 includes a dc isolating capacitor 176 in series with a line terminating resistor 178.

The first voltage inlet pathway 152 extends from contact 142 to a first input of a differential amplifier 168. The first voltage inlet pathway includes a capacitor 192. The second voltage inlet pathway 154 extends from contact 144 to a second input of the differential amplifier 168 and includes a capacitor 194. Capacitors 192, 194 are matched within 5%. The differential amplifier 168 of the present invention provides measuring means in electrical communication with the first and second voltage inlet pathways 152, 154.

The circuit 140 of the present invention operates in the following manner. In the same manner as the circuit 10 of FIG. 1, the circuit 140 is attached to the first and second conductors 26, 28 of the telecommunications line 30 and to earth ground 34 using contacts 122, 124 and 132 respectively. AC signals and high voltage DC is placed on the metal insulation of the telecommunications pair 30 using oscillator 160, DC power source 162, and capacitor 196. The AC signal is coupled to conductors 26, 28, corresponding to ring and tip of the telecommunication pair. The AC signal is loaded to ground 34 through connection 146 by the first and second balanced output pathways 148, 150. Resistors 186 and 190 as well as capacitors 184, 188, must be balanced to a variance less than the smallest desired value of measurement by the circuit 140. At the same time, DC current supplied by DC power source 162 is provided to the first and second high voltage bias pathways 172, 174 to break down any high impedance faults and allows the AC signal to pass through the ring or tip conductors, revealing the fault.

The AC signal is reflected back to the stress test circuit 140 through contacts 142, 144 while resistor 178 and capacitor 176 filter out unwanted noise. Then, the AC signal passes through isolation capacitors 192 and 194 to the differential amplifier 168. The differential amplifier 168 receives metallic voltage signals from voltage inlet pathways 152, 154 and measures the voltage difference. Any difference of the capacitance between the two conductors 26, 28, will cause amplitude and phase changes of the coupled tone which is measured by the differential amplifier 168. The device 110 provides similar stress test results when using standard testing protocols under similar circumstances as devices employing the circuit 10 shown in FIG. 1. Any amplitude or phase changes of the coupled tone measured by the differential amplifier 168 are converted to a corresponding expression of noise or balance and fed to display 114. A log amplifier (not shown) may be provided for converting the voltage difference from amplifier 168 to a measure of noise in decibels, typically in units of decibels reference noise (dBrn), or a measure of balance also in decibels. The DC current is also reflected back into the stress test circuit 140 through connections 142 and 144 to ground 158 through resistors 180 and 182.

Thus, circuit 140 performs a stress test similar to that performed by the circuit 10 of FIG. 1, however, the circuit 140 eliminates the need for a technician to vet capacitors so that the circuit 140 will operate properly. As shown in FIG. 1 the first voltage inlet pathway 28 extends from first contact 14 to a first input of the differential amplifier 21 and includes a first balanced capacitor 34. The second voltage inlet pathway extends from second contact 18 to a second input of the differential amplifier 21. In the circuit 10, the AC signal is applied to the first and second balanced outlet pathways at node 35 and is passed to conductors 26, 28 of the telecommunications pair 30 through balanced resistors 32, 36 and balanced capacitors 34, 38. The AC signal is reflected back to the stress test circuit 10 through the contacts 14, 18 and the balanced capacitors 34, 38 to the first and second inputs of the differential amplifier 21. Thus, any return AC signals from the first and second conductors 26, 28 of a telecommunications pair 30 is passed through the capacitors 34, 38 before reaching the differential amplifier 21. As a result, capacitors 34, 38 of the circuit 10 are required to be matched within 0.05% as described above. In contrast the circuit 140 of the present invention shown in FIG. 3, provides for relocation of the first and second voltage inlet pathways 152, 154, such that they are now connected to what would have been nodes 33, 37 of the circuit 10. Hence, capacitors 184, 188 only function to apply the desired AC signal onto the first and second conductors 26, 28 of the paired telecommunications line 30 and do not also serve to isolate the differential amplifier 168 and other components of the measurement circuitry from damage from DC current because the measurement of the AC signals as they return from the conductors 26, 28 of the telecommunications line 30 is taken before the AC signals reach capacitors 184, 188 a second time. Thus, only capacitors with values of 2.2 microfarads and a tolerance of 0.5% are required. Because manufacturing tolerances provide that capacitors marked with equal values will be matched within 0.5%, the need for vetting of capacitors is eliminated.

A need still exists to protect the measurement circuitry 168 from high voltage DC current in the circuit 140. Consequently, new capacitors 192, 194 have been included with values of only 1 microfarad and lose tolerances to prevent DC current from reaching the measurement circuitry 168 of the test instrument 110. Only capacitors of low values and tolerances are required because the impedance of the measurement circuit is very high. Furthermore, the load and isolation tasks of the original capacitors 34, 38 of the circuit 10 shown in FIG. 1 have been split by adding additional capacitors. In the circuit 140, the load task is performed by capacitors 184, 188 and the isolation task is performed by capacitors 192, 194. Thus, the tolerance requirements for the capacitors of the circuit 140 are redistributed among more components.

Each balanced outlet pathway 148, 150 includes a capacitor 184, 188 in series with a resistor 186, 190. Although the capacitors 184, 188 are positioned proximate the earth ground 34 in the circuit 140, it is to be understood that the positions of the capacitors 184, 188 and the resistors 186, 190 could be swapped such that the resistors 186, 190 are positioned proximate the node 158. However, by providing the capacitors 184, 188 connected directly to earth ground 158 as shown in FIG. 3, capacitors 184, 188 can be varied by simply adding or removing parallel capacitance with a transistor to ground. This enables the circuit 140 to auto-calibrate efficiently if so desired, allowing capacitors 184 and 188 to vary as much as 10% in value without fear of ruining the quality of measurement by the stress test circuit 140.

As can be seen, this invention provides a more efficient way of performing the stress test because it does not require a technician to vet capacitors. In addition, because the need to vet capacitors is eliminated, the circuit 140 is less prone to human error and therefore is more reliable. Finally, the amount of time required to assemble the circuit is reduced which results in reduced labor cost, making this circuit 140 more economical than the previous stress test circuits.

While preferred embodiments of the present invention are shown and described, it is envisioned that those skilled in the art may devise various modifications of the present invention without departing from the spirit and scope of the appended claims.

The invention claimed is:

1. An apparatus for measuring noise in a paired line including:
a first contact engagable with a first conductor of said line;
a second contact engagable with a second conductor of said line;
measuring means in electrical communication with said first and second contacts for measuring metallic voltage signals generated by an imbalance between said first conductor and said second conductor representative of a noise in said line;
a first voltage inlet pathway across which said measuring means electrically communicates with said first contact;
a second voltage inlet pathway across which said measuring means electrically communicates with said second contact;
a first balanced pathway in electrical communication with said first contact;
a second balanced pathway in electrical communication with said second contact, said first balanced pathway being substantially electrically balanced with said second balanced pathway;
an alternating current source electrically connected to said first contact across said first balanced pathway and to said second contact across said second balanced pathway to provide alternating current to said paired line; and
a ground pathway connected to said alternating current source, said ground pathway having ground minimizing means for substantially minimizing flow of power influence current to ground;
wherein at least one of said balanced pathways and said voltage inlet pathways partially share the same line from at least one of said contacts so that any alternating current signal coming from said line is received by said measuring means prior to being transmitted through all of said balanced pathway.

2. The apparatus of claim 1, wherein said first balanced pathway and said first voltage inlet pathway partially share the same line from said first contact and said second balanced pathway and said second voltage inlet pathway partially share the same line from said second contact.

3. The apparatus of claim 1 wherein said first voltage inlet pathway includes a first capacitor and said second voltage inlet pathway includes a second capacitor; and wherein the required matching rate of said first and second capacitors is 5%.

4. The apparatus of claim 1 wherein said first balanced pathway includes a first capacitor and said second balanced pathway includes a second capacitor, and wherein the required matching rate of said first and second capacitors is 0.5%.

5. An apparatus for measuring noise in a paired line including:
a first contact engagable with a first conductor of said line;
a second contact engagable with a second conductor of said line;
measuring means in electrical communication with said first and second contacts for measuring a metallic voltage signals between said first conductor and said second conductor representative of a noise in said line;
a first voltage inlet pathway comprising a first capacitor across which said measuring means electrically communicates with said first contact;
a second voltage inlet pathway comprising a second capacitor across which said measuring means electrically communicates with said second contact;
a first balanced pathway comprising a third capacitor in electrical communication with said first contact for applying an alternating current signal on said first conductor;
a second balanced pathway comprising a fourth capacitor in electrical communication with said second contact for applying an alternating current signal on said second conductor, said first balanced pathway being substantially electrically balanced with said second balanced pathway;
an alternating current source electrically connected to said first contact across said first balanced pathway and to said second contact across said second balanced pathway to provide alternating current to said paired line; and
a ground pathway in electrical communication with said alternating current source and ground, said ground pathway having a capacitor for minimizing the flow of power influencing current to ground.

6. An apparatus as defined in claim 5, further including:
a terminating pathway connected to said first balanced outlet pathway proximal said first contact upstream from said first conductor and further connected to said second balanced outlet pathway proximal said second contact upstream from said second conductor, said terminating pathway having an isolating capacitor and a line terminating resistor.

7. An apparatus as defined in claim 5, wherein said measuring means is a differential amplifier.

8. An improved apparatus for measuring noise in a paired line including:
a first contact engagable with a first conductor of said line;
a second contact engagable with a second conductor of said line;
measuring means in electrical communication with said first and second contacts for measuring metallic voltage signals generated by an imbalance between said first conductor and said second conductor representative of a noise in said line;
a first voltage inlet pathway across which said measuring means electrically communicates with said first contact;
a second voltage inlet pathway across which said measuring means electrically communicates with said second contact;
a first balanced pathway having a first capacitor directly connected to ground with no resistor therebetween that is in electrical communication with said first contact;
a second balanced pathway having a second capacitor directly connected to ground with no resistor therebetween, said second balanced pathway being in electrical communication with said second contact and substantially electrically balanced with said first balanced pathway;
an alternating current source electrically connected to said first contact across said first balanced pathway and to said second contact across said second balanced pathway to provide alternating current to said paired line; and
a ground pathway connected to said alternating current source, said ground pathway having ground minimizing means for substantially minimizing flow of power influence current to ground.

9. The apparatus of claim 8, further comprising a transistor that is in electrical communication with at least one of said capacitors and ground, thereby allowing said apparatus to auto-calibrate.

10. A method for measuring noise in a paired line comprising:
generating a first metallic voltage signal in a first conductor of said paired line using a first capacitor and a second metallic voltage signal in a second conductor of said paired line using a second capacitor;
transmitting said first and second metallic voltage signals from said first and second conductors to measuring means without passing said signals through either of said first or second capacitors; and
measuring a differential between said first and second metallic voltage signals caused by said imbalance between said first and second conductors representative of a noise in said line.
